(19) United States
(12) Patent Application Publication
(10) Pub. No.: US 2005/0105278 A1
(43) Pub. Date: May 19, 2005

(54) Apparatus and method for dissipating thermal energy generated by a peripheral card

(76) Inventor: Peter Rae Shintani, San Diego, CA (US)

Correspondence Address: Steven L. Nichols;Rader, Fishman & Grauer PLLC, River Park Corporate Center One, River Front Pkwy., Ste. 150, South Jordan, UT, 84095, US

(21) Appl. No.: 10/810,389

(22) Filed: Mar. 26, 2004

Related U.S. Application Data
(60) Provisional application No. 60/520,589, filed on Nov. 17, 2003.

(51) Int. Cl. H05K 7/20

(52) U.S. Cl. 361/720; 361/704; 257/718

(57) ABSTRACT

In one of many possible embodiments, the present invention provides a host device that includes a positionable cooling element for dissipating thermal energy generated by a peripheral card inserted into the host device, a positioning mechanism coupled to the cooling element, and a latching mechanism coupled to the positioning mechanism. The movement of the latching mechanism from a first position to a second position causes the positioning mechanism to translate the cooling element towards the peripheral card.

### RELATED APPLICATIONS

The present application claims priority under 35 U.S.C. § 119(e) from previously-filed U.S. Provisional Patent Application No. 60/520,589, filed Nov. 17, 2003 and entitled “Innovative Method for Thermal Control of a Removable Module,” which is incorporated herein by reference in its entirety.

### TECHNICAL FIELD

The present invention relates to the field of dissipating thermal energy generated by an electrical device.

### BACKGROUND

Set top boxes, cable boxes, servers, laptops, computers, televisions, and other host devices often include expansion slots wherein peripheral cards may be inserted. A peripheral card gives an host device added functionality and/or features. One type of peripheral card may be a removable security card such as a the CableCARD™ used in the cable industry for example. A removable security module, when inserted in a properly configured set top box, television, or other host device, enables delivery and decryption of encrypted digital video programming and other services. Other types of peripheral cards include, but are not limited to, PCMCIA cards.

A peripheral card generates thermal energy or heat while operating within a host device. Furthermore, because a peripheral card is at least partially enclosed by the host device, the effective surface temperature of a peripheral card is also affected by the internal heat generation of the host device. It is important from a user safety point of view that a peripheral card's surface temperature is constrained to stay within an allowable range. Limiting the temperature of a peripheral card also ensures proper functionality of the peripheral card. Furthermore, an excessive amount of thermal energy generated by a peripheral card may negatively affect other electronic components within a host device.

For these and other reasons, many systems within which peripheral cards operate have standards outlining maximum allowable thermal energy dissipation levels for peripheral cards. For example, in some applications, security cards used in the cable industry may be permitted to dissipate approximately 5 watts of peak power and 2.5 watts of power over a 10 second period. It is often difficult to maintain a sufficiently low temperature level for peripheral cards, especially where the peripheral cards are required to operate for sustained periods of time and/or in environments with a high ambient temperature.

### SUMMARY

In one of many possible embodiments, the present invention provides a host device that includes a positionable cooling element for dissipating thermal energy generated by a peripheral card inserted into the host device, a positioning mechanism coupled to the cooling element, and a latching mechanism coupled to the positioning mechanism. The movement of the latching mechanism from a first position to a second position causes the positioning mechanism to translate the cooling element towards the peripheral card.

### BRIEF DESCRIPTION OF THE DRAWINGS

The accompanying drawings illustrate various embodiments of the present invention and are a part of the specification. The illustrated embodiments are merely examples of the present invention and do not limit the scope of the invention.

FIG. 1 illustrates an exemplary host device according to one exemplary embodiment of the present invention.

FIG. 2 is a cross-sectional side view of a host device illustrating a positionable cooling element according to one exemplary embodiment of the present invention.

FIG. 3 is a cross-sectional side view of a host device illustrating a positionable cooling element that has been translated towards a peripheral card according to one exemplary embodiment of the present invention.

FIG. 4 illustrates a host device having first and second cooling elements that are translated towards a peripheral card according to one exemplary embodiment of the present invention.

FIG. 5 is a cross-sectional side view of a host device illustrating a positioning mechanism that is an electromechanical device according to one exemplary embodiment of the present invention.

FIG. 6 is a cross-sectional side view of a host device illustrating a spring loaded locking mechanism according to one exemplary embodiment of the present invention.

FIG. 7 illustrates a host device having an engaging device that causes a cooling element to translate towards a peripheral card and a card guide assembly according to an exemplary embodiment of the present invention.

FIG. 8 is a cross-sectional side view of a host device illustrating a rotatable socket that allows a peripheral card to rotate towards a fixed cooling element according to one exemplary embodiment of the present invention.

FIG. 9 illustrates a host device that includes a fixed cooling element and a moveable card guide that translates towards the fixed cooling element according to an exemplary embodiment of the present invention.

FIG. 10 is a flow chart illustrating an exemplary method of dissipating thermal energy generated by a peripheral card in a host device according to an exemplary embodiment of the present invention.

FIG. 11 is flow chart illustrating another exemplary method of dissipating thermal energy generated by a peripheral card in a host device according to an exemplary embodiment of the present invention.

FIG. 12 is a flow chart illustrating another exemplary method of dissipating thermal energy generated by a peripheral card in a host device according to an exemplary embodiment of the present invention.

FIG. 13 is a flow chart illustrating another exemplary method of dissipating thermal energy generated by a peripheral card in a host device according to an exemplary embodiment of the present invention.

FIG. 14 is a flow chart illustrating another exemplary method of dissipating thermal energy generated by a peripheral card in a host device according to an exemplary embodiment of the present invention.

Throughout the drawings, identical reference numbers designate similar, but not necessarily identical, elements.

### DETAILED DESCRIPTION

An apparatus and method for dissipating thermal energy generated by a peripheral card that is inserted into a host device are explained herein. In the following description, for purposes of explanation, numerous specific details are set forth in order to provide a thorough understanding of the present system and method. It will be apparent, however, to one skilled in the art that the present method and system may be practiced without these specific details. Reference in the specification to “one embodiment” or “an embodiment” means that a particular feature, structure, or characteristic described in connection with the embodiment is included in at least one embodiment. The appearance of the phrase “in one embodiment” in various places in the specification are not necessarily all referring to the same embodiment.

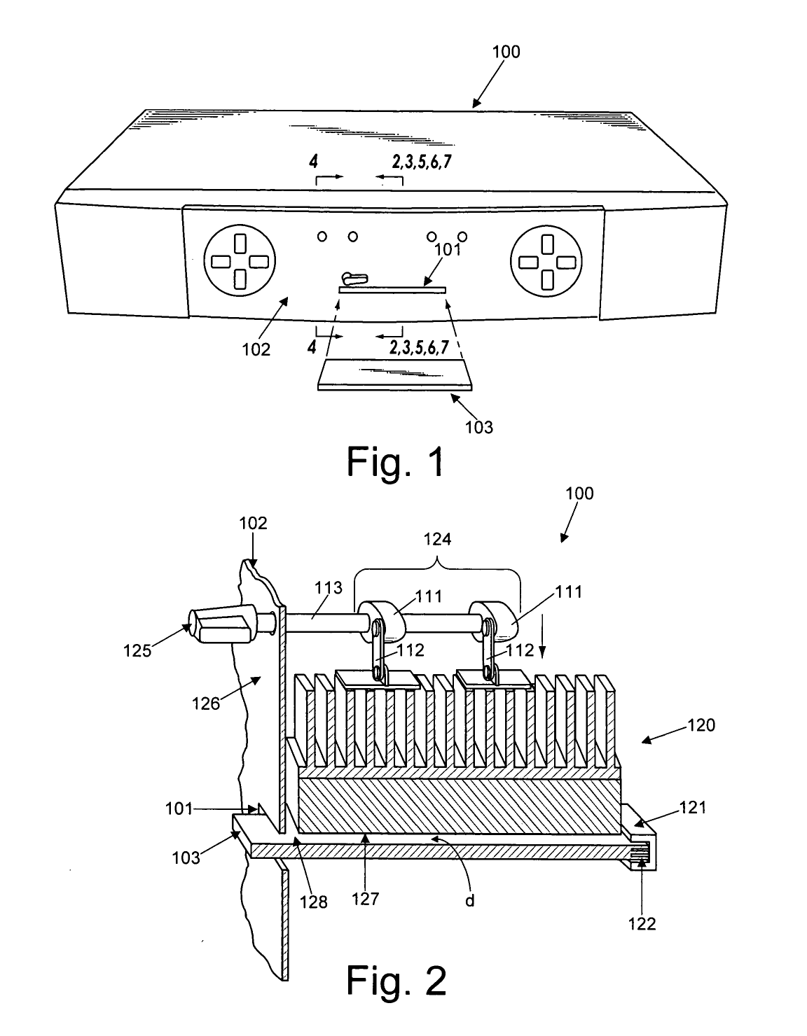

FIG. 1 shows an exemplary host device (100) according to one exemplary embodiment of the present invention. The host device (100) may be a set top box, cable box, server, laptop, computer, television, or any other electronic device configured to function with a peripheral card (103).

As shown in FIG. 1, the host device (100) may include an opening (101) in its housing (102) that is configured to receive a removable peripheral card (103). The peripheral card (103) may be manually inserted into the opening (101) of the host device (100) by a user of the host device (100), for example. The opening (101) is located on the front side of the host device (100) in FIG. 1 for illustrative purposes only. However, it will be recognized that the opening (101) maybe located on any surface of the host device (100).

According to an exemplary embodiment of the present invention, the peripheral card (103) of FIG. 1 may be a removable security card, PCMCIA card, network card, or any other removable module that may be inserted into a host device (100) such that the peripheral card (103) is at least partially disposed within the housing (102) of the host device (100). The peripheral card (103) may be partially or entirely disposed within the housing (102) of the host device (100) according to one exemplary embodiment.

FIG. 2 is a cross-sectional side view of the host device (100) shown in FIG. 1. FIG. 2 shows that the host device (100) may include components located within its housing (102) to facilitate the insertion of a peripheral card (103). For example, as shown in FIG. 2, the host device (100) may include a socket (121) having electrical connection pins (122) that establish an electrical connection with a peripheral card (103) that has been inserted into the host device (100). The electrical connection allows the host device (100) to use the functions provided by the peripheral card (103). The host device (100) may also include one or more internal guides (not shown) for guiding the peripheral card (103) such that the peripheral card (103) makes a proper connection with the electrical connection pins (122) in the socket (121).

In one exemplary embodiment of the present invention, as shown in FIG. 2, the host device (100) may include a positionable cooling element (120) that is configured to dissipate thermal energy generated by a peripheral card (103) that has been inserted into the host device (100). As shown in FIG. 2, the bottom surface (127) of the cooling element (125) is separated from the top surface (128) of the inserted peripheral card (103) by a distance d. The length of d may vary as best serves a particular application.

The cooling element (120) of FIG. 2 is configured to control the temperature of the peripheral card (103) that is inserted into the host device (100). In particular, the cooling element (120) dissipates thermal energy produced by the peripheral card (103) such that the peripheral card (103) operates within an acceptable temperature range. Acceptable temperature ranges of the peripheral card (103) will vary as best serves a particular application.

The cooling element (120) shown in FIG. 2 is a thermal energy sink for illustrative purposes only. According to one exemplary embodiment, the cooling element (120) may be an active or a passive cooling element. For example, the cooling element (120) may be, but is not limited to, a thermal energy sink, fan, blower, turbo cooler, or thermal energy spreader. If necessary, the cooling device (120) may be powered by an internal power supply (not shown) of the host device (100).

FIG. 2 illustrates that the cooling element (120) may be coupled to a positioning mechanism (124) within the host device (100). The positioning mechanism (124) shown in FIG. 2 is a mechanical device including a two cams (111) each coupled to 2-bar kinematic links (112). The cams (111) are coupled to a shaft (113) which is coupled to a latching mechanism (125). The positioning mechanism (124) of FIG. 2 includes two cams (111) for illustrative purposes only. According to one embodiment of the present invention, the positioning mechanism (124) may include any number of cams (111) and corresponding kinematic links (112) as best serves a particular application. Furthermore, the positioning mechanism (124) may be any other mechanical or electromechanical device configured to move the cooling element (120).

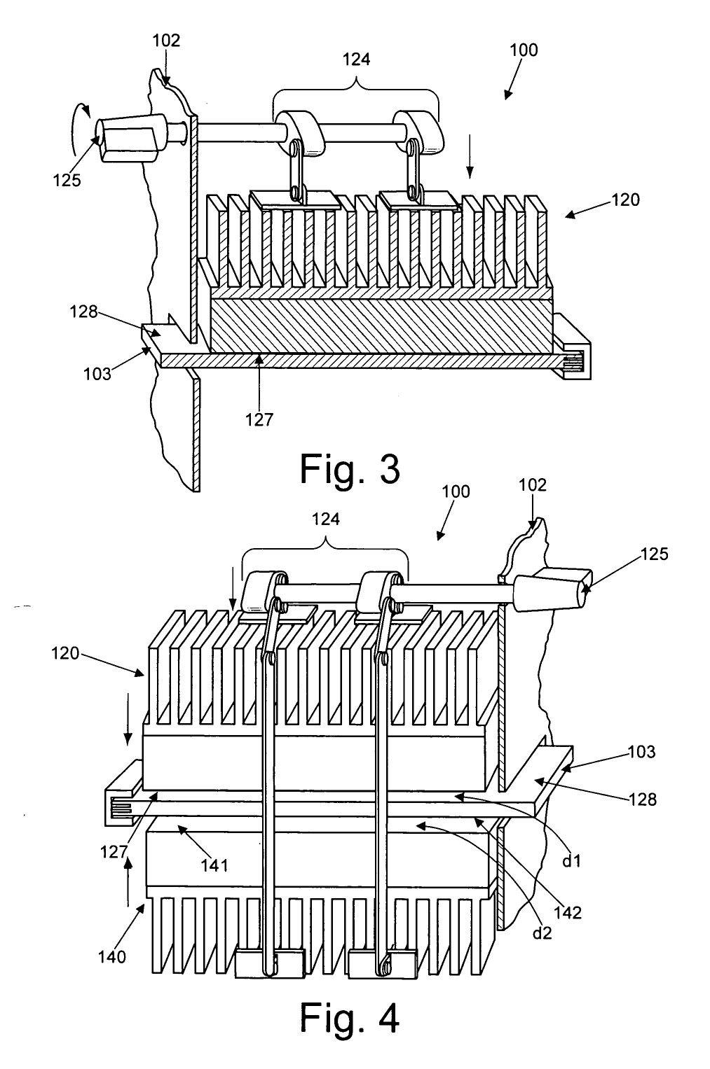

The positioning mechanism (124) may also be coupled to a latching mechanism (125) that is located on the outer surface (126) of the housing (102) of the host device (100). In one embodiment, after the peripheral card (103) has been inserted into the host device (100), the latching mechanism (125) may be displaced from a first position to a second position. FIG. 2 shows the latching mechanism (125) in the first position and FIG. 3 shows the latching mechanism (125) after it has been displaced to the second position. The displacement of the latching mechanism (125) from the first to the second position causes the positioning mechanism (124) to translate the cooling element (120) towards the inserted peripheral card (103) such that the cooling element (120) can adequately dissipate thermal energy generated by the inserted peripheral card (103).

For example, the displacement of the latching mechanism (125) from the first to the second position may cause the positioning mechanism (124) to translate the cooling element (120) towards the peripheral card (103) such that the bottom surface (127) of the cooling element (120) is coupled to the top surface (128) of the peripheral card (103), as shown in FIG. 3. However, according to an exemplary embodiment, the positioning mechanism (124) may translate the cooling element (120) to any position that is optimal for cooling the peripheral card (103).

When the peripheral card (103) is to be removed from the host device (100), the latching mechanism (125) may be displaced from the second position to the first position. The displacement of the latching mechanism (125) from the second position to the first position causes positioning mechanism (124) to move the cooling element (120) back to its original position which is a distance d from the top surface (128) of the inserted peripheral card (103). The peripheral card (103) may then be removed from the host device (100).

The latching mechanism (125) of FIGS. 2 and 3 may be of one of the many different types of mechanisms that may cause the positioning mechanism (124) to position the cooling element (120). For example, the latching mechanism (125) may be a lever that may be rotated from the first to the second position, as illustrated in FIGS. 2 and 3. According to one exemplary embodiment, the latching mechanism (125) may be any mechanical or electrical device or mechanism configured to cause the positioning mechanism (124) to translate the cooling element (120) towards the peripheral card (103).

FIG. 4 illustrates an alternative embodiment wherein the host device (100) includes positionable first and second cooling elements (120, 140). As shown in FIG. 4, the bottom surface (127) of the first positionable cooling element (120) is separated from the top surface (128) of the inserted peripheral card (103) by a distance d₁. The bottom surface (141) of the second positionable cooling element (140) is separated from a bottom surface (142) of the inserted peripheral card (103) by a distance d₂. The distances d₁ and d₂ may vary as best serves a particular application.

FIG. 4 illustrates that the first and second cooling elements (120, 140) may each be coupled to the positioning mechanism (124) within the host device (100). The positioning mechanism (124) may also be coupled to a latching mechanism (125) that is located on the outer surface (126) of the housing (102) of the host device (100). In one embodiment, after the peripheral card (103) has been inserted into the host device (100), the latching mechanism (125) may be displaced from a first position to a second position. The displacement of the latching mechanism (125) from the first to the second position causes the positioning mechanism (124) to translate the first cooling element (120) towards the top surface (128) of the inserted peripheral card (103). Likewise the displacement of the latching mechanism (125) from the first to the second position causes the positioning mechanism (124) to translate the second cooling element (140) towards the bottom surface (142) of the inserted peripheral card (103).

For example, the displacement of the latching mechanism (125) from the first to the second position may cause the positioning mechanism (124) to translate the first cooling element (120) such that the bottom surface (127) of the first cooling element (120) is coupled to the top surface (128) of the peripheral card (103). The displacement of the latching mechanism (125) from the first to the second position may also cause the positioning mechanism (124) to translate the second cooling element (140) such that the bottom surface (141) of the second cooling element (140) is coupled to the bottom surface (142) of the peripheral card (103). However, according to an exemplary embodiment, the positioning mechanism (124) may move the first and second cooling elements (120, 140) into any positions that are optimal for cooling the peripheral card (103).

The first and second cooling elements (120, 140) may also serve to secure the peripheral card (103) into place once it has been inserted into the host device (100). For example, when the latching mechanism (125) is displaced from the first to the second position, the peripheral card (103) may be effectively “sandwiched” between the translated first and second cooling elements (120, 140). In one exemplary embodiment, the peripheral card (103) may not be properly removed from the host device (100) without first displacing the latching mechanism (125) from the second position back to the first position. For illustrative purposes only, the host device (100) will include only one cooling element (120) in the following examples describing the remaining embodiments of the present invention. However, it will be recognized that a second cooling element (140) and/or additional cooling elements may be used.

The displacement of the latching mechanism (125) from the first position to the second position may also be configured to indicate to the host device (100) that the peripheral card (103) is correctly positioned within the host device (100). In one exemplary embodiment, if the latching mechanism (125) is in the second position, a sensor (not shown) may indicate via an electrical signal to the host device (100) that the peripheral card (103) is correctly positioned within the host device (100). The indication of correct positioning of the peripheral card (103) within the host device (100) may also serve to ensure that the host device (100) “knows” in advance of the removal of the peripheral card (103) because the latching mechanism (125) would have to be displaced from the second position back to the first position before the peripheral card (103) can be removed.

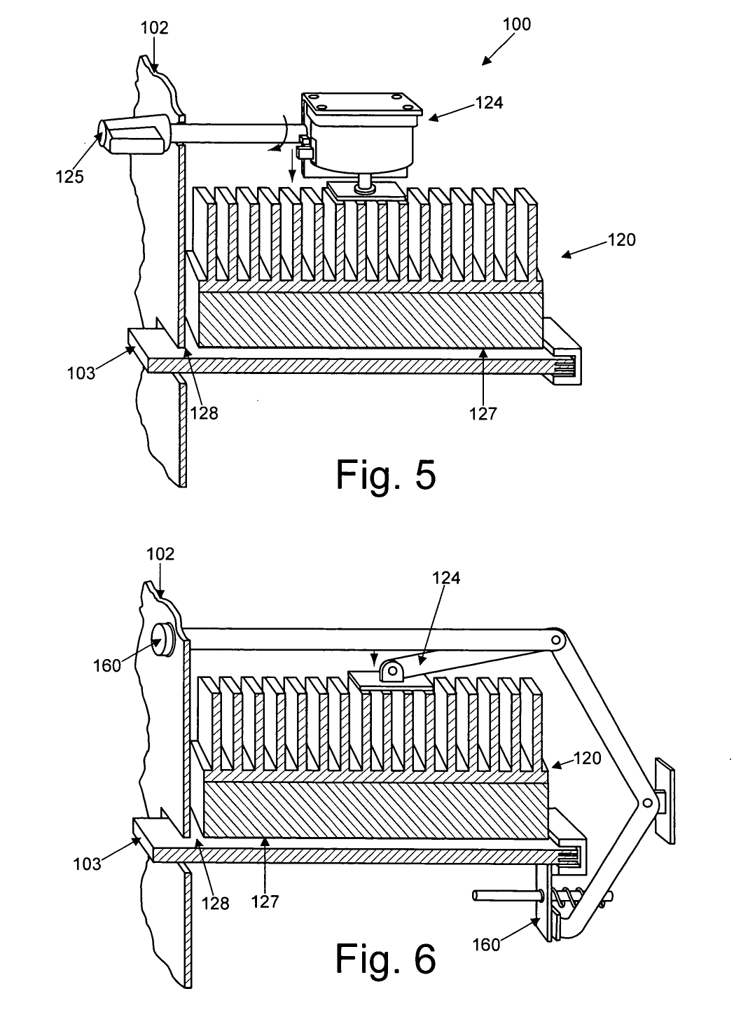

FIG. 5 illustrates an alternative embodiment wherein the positioning mechanism (124) is an electromechanical device such as a motor, solenoid, or other device configured to electromechanically position the cooling element (120). The movement of the latching mechanism (125) from the first to the second position causes the electromechanical device (124) to electromechanically translate the cooling element (120) towards the inserted peripheral card (103).

In yet another alternative embodiment (not shown), a sensor may indicate via an electrical signal to the electromechanical device (124) that the peripheral card (103) has been correctly positioned within the host device (100). Upon receiving the indication that the peripheral card (103) has been correctly positioned with the host device (100), the electromechanical device may translate the cooling element (120) towards the inserted peripheral card (103). In this embodiment, the latching mechanism (125) may not be necessary.

FIG. 6 illustrates an exemplary embodiment wherein the host device (100) includes a spring loaded locking mechanism (160) that locks or secures an inserted peripheral card (103) into place when a sufficient amount of force is imparted by a user on the peripheral card (103) as the peripheral card (103) is being inserted into the host device (100). The spring loaded locking mechanism (160) is coupled to the positioning mechanism (124). When the spring loaded locking mechanism (160) engages the inserted peripheral card (103), the spring loaded locking mechanism (160) may cause the positioning mechanism (124) to translate the cooling element (120) towards the inserted peripheral card (103).

As shown in FIG. 6, a release button (161) may also be included on the outer surface of the housing of the host device (100). The release button (161) may be coupled to the spring loaded locking mechanism (160), as shown in FIG. 6. The release button (161), when pressed by a user, may cause the spring loaded locking mechanism (160) to in turn cause the positioning mechanism (124) to translate the cooling element (120) back to its original position and the peripheral card (103) to be ejected from the host device (100). In an alternative embodiment (not shown), the host device (100) may automatically translate the cooling element (120) back to its original position and eject the peripheral card (103) from the host device (100) upon receiving a command via a user or program.

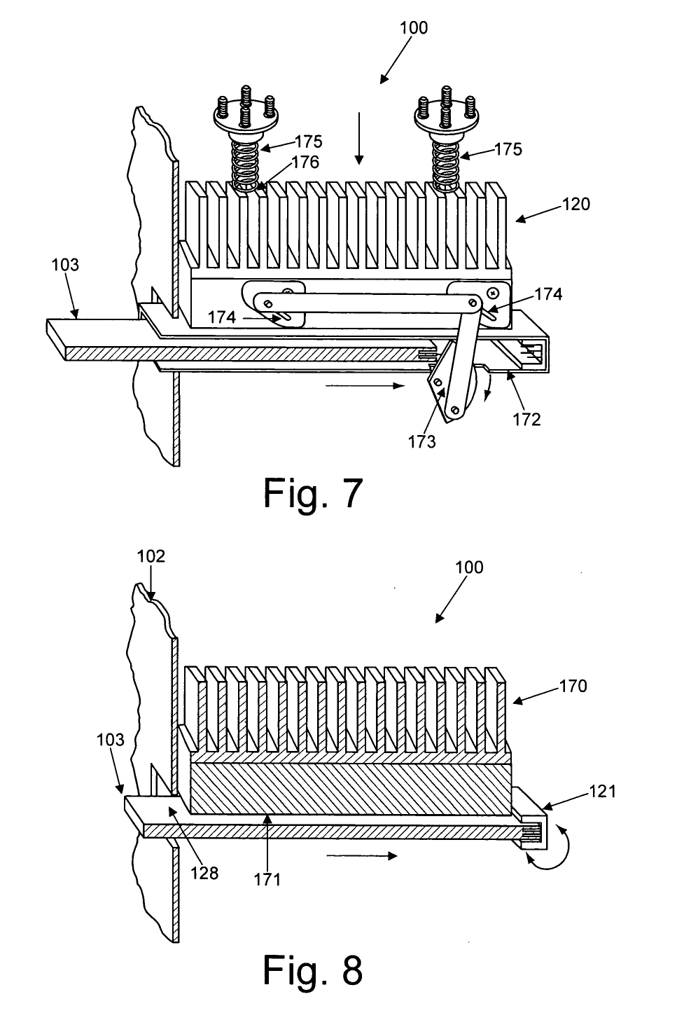

FIG. 7 illustrates yet another embodiment wherein the host device (100) includes a card guide assembly (172) into which a peripheral card (103) is inserted. The card guide assembly (172) is coupled to an engaging device (173) that protrudes into the space within the card guide assembly (172) wherein the peripheral card (103) is inserted. The engaging device (173) may be a tab, pin, or the like. The engaging device (173), as shown in FIG. 7, is coupled to a cooling element (120). When the peripheral card (103) is inserted into the guide card assembly (172), the peripheral card (103) is engaged by the engaging device (173). The movement of the peripheral card (103) towards the socket (121) causes the engaging device (173) to cause the cooling element (120) to translate down one or more guide tracks (174) towards the peripheral card (103). In an alternative embodiment, there may be more than one engaging device (173) and/or guide track (174).

As shown in FIG. 7, the cooling element (120) may be coupled to one or more springs (175) that force the cooling element (120) to translate back up the guide tracks (174) to its original position when the peripheral card (103) is removed from the host device (100). The springs (175) may be coupled to the top surface (176) of the cooling element (120), as shown in FIG. 7 or they may alternatively be coupled to any other suitable surface of the cooling element (120).

FIG. 8 illustrates an exemplary embodiment wherein the host device (100) includes a fixed cooling element (170) that remains in a fixed position. In this embodiment, the socket (121) into which the peripheral card (103) is inserted is configured to be able to rotate as shown in FIG. 8. Thus, an inserted peripheral card (103) may be rotated up or down such that some or all of the top surface (128) of the peripheral card (103) makes contact with the bottom surface (171) of the fixed cooling element (170).

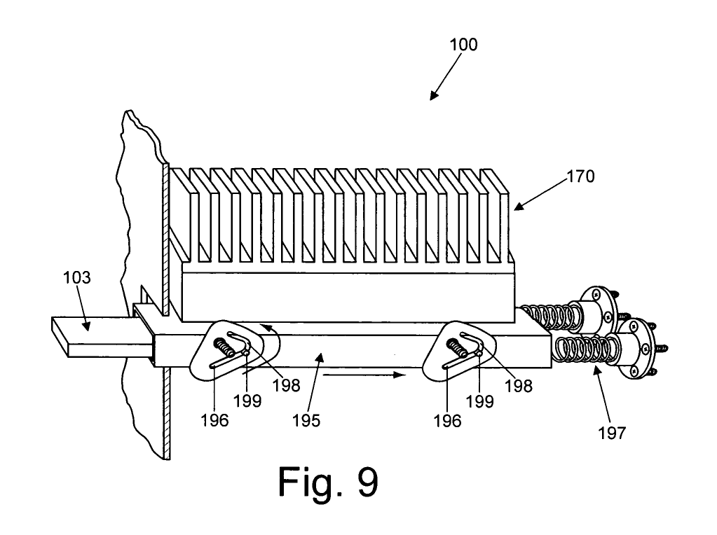

FIG. 9 illustrates another exemplary embodiment wherein the host device (100) includes a fixed cooling element (170) that remains in a fixed position. In this embodiment, the host device (100) includes a moveable card guide assembly (I 95) into which a peripheral card (103) is inserted. The moveable card guide assembly (195) includes a socket (not shown) at one of its ends. The end of the moveable card guide assembly (195) having the socket is coupled to one or more springs (197). The moveable card guide assembly (195) is coupled to one or more members (199) that are configured to translate in a motion defined by a V-shaped guide track (196). The members (199) may be pins, for example, that extend from the V-shaped guide tracks (196). Each of the V-shaped guide tracks (196) may be coupled to a support structure or the like found in the host device (100).

In the embodiment illustrated in FIG. 9, a user may insert the peripheral card (103) into the moveable card guide assembly (195) and apply pressure to the peripheral card (103) such the peripheral card (103) and the moveable card guide assembly (195) translate in a direction defined by the V-shaped guide tracks (196). This translation of the moveable card guide assembly (195) causes the springs (197) to compress. When the peripheral card (103) and the moveable card guide assembly (195) are pushed past the apex (198) of the V-shaped guide tracks (196), the compressed springs (197) decompress and force the moveable card guide assembly (195) and the peripheral card (103) to translate up the V-shaped guide tracks (196) towards the fixed cooling element (170). The peripheral card (103) may be removed from the host device (100) by pushing the peripheral card (103) and the moveable card guide assembly (195) back towards the apex (198) of the V-shaped guide tracks (196). A release button (not shown) may also perform the removal of the peripheral card (103) from the host device (100).

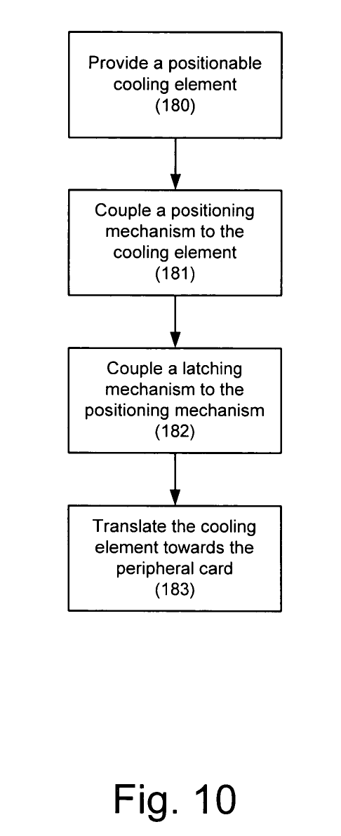

FIG. 10 is a flow chart illustrating an exemplary method of dissipating thermal energy generated by a peripheral card in a host device according to an exemplary embodiment of the present invention. First, a positionable cooling element is provided (step 180). A positioning mechanism is coupled to the cooling element (step 181). A latching mechanism is coupled to the positioning mechanism (step 182). The cooling element is then translated towards the peripheral card (step 183) by moving the latching mechanism from a first position to a second position.

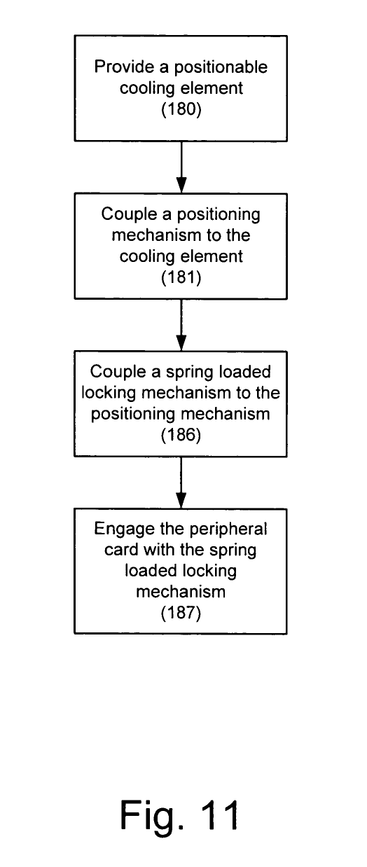

FIG. 11 is a flow chart illustrating another exemplary method of dissipating thermal energy generated by a peripheral card in a host device according to an exemplary embodiment of the present invention. As is the method described in connection with FIG. 10, a positionable cooling element is first provided (step 180). A positioning mechanism is coupled to the cooling element (step 181). A spring loaded locking mechanism is then coupled to the positioning mechanism (step 186). When a peripheral card is inserted into the host device, the spring loaded locking mechanism engages the peripheral card (step 187). The engagement of the peripheral card causes cooling element to translate towards the peripheral card.

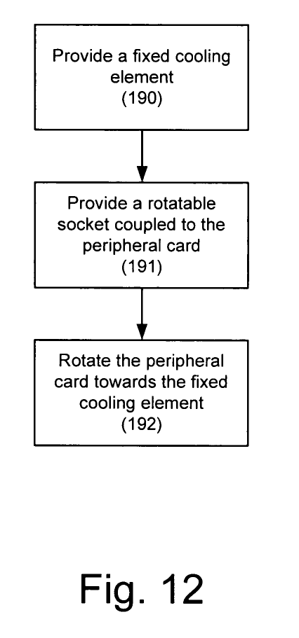

FIG. 12 is a flow chart illustrating another exemplary method of dissipating thermal energy generated by a peripheral card in a host device according to an exemplary embodiment of the present invention. A fixed cooling element is first provided (step 190). A rotatable socket coupled to the peripheral card is also provided (step 191). The peripheral card is then rotated towards the fixed cooling element (step 192).

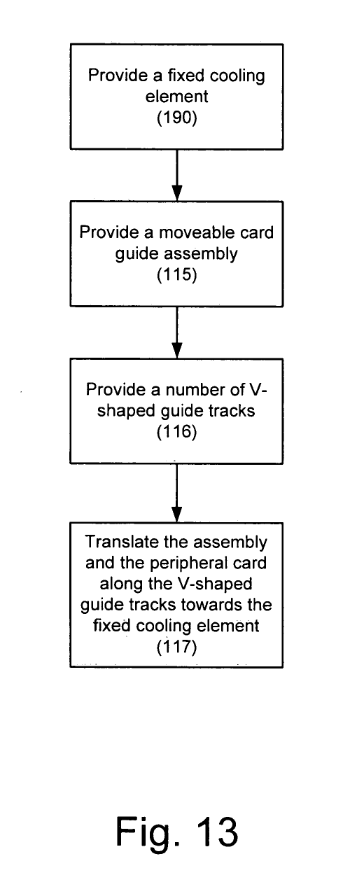

FIG. 13 is a flow chart illustrating another exemplary method of dissipating thermal energy generated by a peripheral card in a host device according to an exemplary embodiment of the present invention. A fixed cooling element is first provided (step 190). A moveable card guide assembly for housing the peripheral card is also is also provided (step 115). A number of V-shaped guide tracks are also provided (step 116). The moveable card guide assembly and the peripheral card are then translated along the V-shaped guide tracks towards the fixed cooling element (step 117).

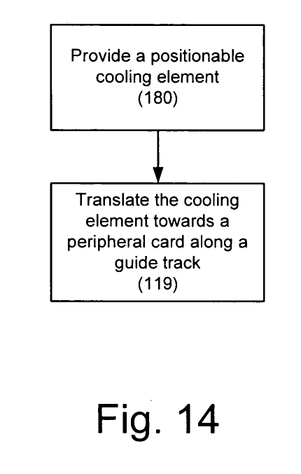

FIG. 14 is a flow chart illustrating another exemplary method of dissipating thermal energy generated by a peripheral card in a host device according to an exemplary embodiment of the present invention. A positionable cooling element is first provided (step 180). The cooling element is then translated towards a peripheral card along a guide track (step 119).

The preceding description has been presented only to illustrate and describe embodiments of invention. It is not intended to be exhaustive or to limit the invention to any precise form disclosed. Many modifications and variations are possible in light of the above teaching. It is intended that the scope of the invention be defined by the following claims.

1. A host device comprising:
a positionable cooling element for dissipating thermal energy generated by a peripheral card inserted into said host device;
a positioning mechanism coupled to said cooling element; and
a latching mechanism coupled to said positioning mechanism;
wherein the movement of said latching mechanism from a first position to a second position causes said positioning mechanism to translate said cooling element towards said peripheral card.

2. The host device of claim 1, wherein said translation of said cooling element towards said peripheral card causes said cooling element to be coupled to said peripheral card.

3. The host device of claim 1, wherein said positioning mechanism comprises:
a two-bar kinematic link coupled to said cooling element;
a cam coupled to said two-bar kinematic link; and
a shaft coupled to said cam and to said latching mechanism.

4. The host device of claim 1, wherein said positioning mechanism comprises an electromechanical device.

5. The host device of claim 4, wherein said electromechanical device is a motor or a solenoid.

6. The host device of claim 1, wherein said latching mechanism is a lever configured to rotate from said first position to said second position.

7. The host device of claim 1, further comprising:
a second positionable cooling element coupled to said positioning mechanism;
wherein said movement of said latching mechanism from said first position to said second position causes said positioning mechanism to translate said second cooling element towards said peripheral card.

8. The host device of claim 7, wherein said second cooling element dissipates thermal energy from a bottom surface of said peripheral card.

9. The host device of claim 1, wherein said movement of said latching mechanism from said first position to said second position causes a signal to be sent to said host device indicating that said peripheral card is properly inserted.

10. The host device of claim 1, wherein said cooling element is an active cooling element or a passive cooling element.

11. The host device of claim 1, wherein said cooling element is a heat sink.

12. An apparatus for translating a cooling element towards a peripheral card comprising:
a two-bar kinematic link coupled to said cooling element;
a cam coupled to said two-bar kinematic link;
a shaft coupled to said cam; and
a latching mechanism coupled to said shaft;
wherein a displacement of said latching mechanism from a first position to a second position causes said translation of said cooling element towards said peripheral card.

13. The apparatus of claim 12, wherein said latching mechanism is a lever configured to rotate from said first position to said second position.

14. The apparatus of claim 12, wherein said cooling element comprises a heat sink.

15. An apparatus for translating a cooling element towards a peripheral card comprising:
an electromechanical device coupled to said cooling element; and
a latching mechanism coupled to said electromechanical device;
wherein a displacement of said latching mechanism from a first position to a second position causes said translation of said cooling element towards said peripheral card.

16. The apparatus of claim 15, wherein said latching mechanism is a lever configured to rotate from said first position to said second position.

17. The apparatus of claim 15, wherein said cooling element comprises a heat sink.

18. A host device comprising:
a positionable cooling element for dissipating thermal energy generated by a peripheral card inserted into said host device;
a positioning mechanism coupled to said cooling element; and
a spring loaded locking mechanism coupled to said positioning mechanism, said spring loaded locking mechanism configured to engage said peripheral card;
wherein said engagement of said peripheral card causes said positioning mechanism to translate said cooling element towards said peripheral card.

19. The host device of claim 18, further comprising:
a release button coupled to said spring loaded locking mechanism;
wherein pressing said release button causes said positioning mechanism to translate said cooling element away from said peripheral card and said peripheral card to eject from said host device.

20. The host device of claim 18, wherein said translation of said cooling element towards said peripheral card causes said cooling element to be coupled to said peripheral card.

21. The host device of claim 18, wherein said cooling element is an active cooling element or a passive cooling element.

22. The host device of claim 18, wherein said cooling element is a heat sink.

23. A host device comprising:
a fixed cooling element for dissipating thermal energy generated by a peripheral card;
a rotatable socket coupled to said peripheral card;
wherein a user rotates said peripheral card towards said fixed cooling element.

24. The host device of claim 23, wherein said cooling element is an active cooling element or a passive cooling element.

25. The host device of claim 23, wherein said cooling element is a heat sink.

26. A host device comprising:
a fixed cooling element for dissipating thermal energy generated by a peripheral card;
a moveable card guide assembly for housing said peripheral card;
one or more members extending from a number of V-shaped guide tracks, said members coupled to said moveable card guide assembly;
wherein said moveable card guide assembly and said peripheral card translate along said V-shaped guide tracks towards said fixed cooling element.

27. The host device of claim 26, further comprising:
a number of springs coupled to said moveable card guide assembly;
wherein said springs compress as said moveable card guide assembly and said peripheral card translate towards an apex of said V-shaped guide tracks and decompress as said moveable card guide assembly and said peripheral card translate past said apex of said V-shaped guide tracks.

28. The host device of claim 26, wherein said cooling element is an active cooling element or a passive cooling element.

29. The host device of claim 26, wherein said cooling element is a heat sink.

30. A host device comprising:
a positionable cooling element for dissipating thermal energy generated by a peripheral card inserted into said host device;
a guide track coupled to said cooling element; and
an engaging device coupled to said cooling element;
wherein said engaging device engages said peripheral card as said peripheral card is inserted into said host device and causes said cooling element to translate along said guide track towards said peripheral card.

31. The host device of claim 30, further comprising:
a number of springs coupled to said cooling element;
wherein said springs cause said cooling element to translate away from said peripheral card when said peripheral card is removed from said host device.

32. The host device of claim 31, wherein said cooling element is an active cooling element or a passive cooling element.

33. The host device of claim 31, wherein said cooling element is a heat sink.

34. A method of dissipating thermal energy generated by a peripheral card in a host device, said method comprising:
providing a positionable cooling element;
coupling a positioning mechanism to said cooling element;
coupling a latching mechanism to said positioning mechanism; and
translating said cooling element towards said peripheral card by moving said latching mechanism from a first position to a second position.

35. The method of claim 34, wherein said step of translating said cooling element comprises coupling said cooling element to said peripheral card.

36. The method of claim 34, wherein said cooling element comprises a plurality of cooling elements.

37. A method of dissipating thermal energy generated by a peripheral card in a host device, said method comprising:
providing a positionable cooling element;
coupling a positioning mechanism to said cooling element;
coupling a spring loaded locking mechanism to said positioning mechanism; and
engaging said peripheral card with said spring loaded locking mechanism;
wherein said engagement of said peripheral card causes said positioning mechanism to translate said cooling element towards said peripheral card.

38. A method of dissipating thermal energy generated by a peripheral card in a host device, said method comprising:
providing a fixed cooling element;
providing a rotatable socket coupled to said peripheral card; and
rotating said peripheral card towards said fixed cooling element.

39. A method of dissipating thermal energy generated by a peripheral card in a host device, said method comprising:
providing a fixed cooling element;
providing a moveable card guide assembly for housing said peripheral card; and
providing a number of V-shaped guide tracks coupled to said moveable card guide assembly;
translating said moveable card guide assembly and said peripheral card along said V-shaped guide tracks towards said fixed cooling element.

40. A method of dissipating thermal energy generated by a peripheral card in a host device, said method comprising:
providing a positionable cooling element; and
translating said cooling element along a guide track towards said peripheral card.

41. A host device comprising:
a positionable cooling element for dissipating thermal energy generated by a peripheral card inserted into said host device;
a positioning means for positioning said cooling element, said positioning means coupled to said cooling element;
a latching means coupled to said positioning means;
wherein the movement of said latching means from a first position to a second position causes said positioning means to translate said cooling element towards said peripheral card.

42. The host device of claim 41, wherein said translation of said cooling element towards said peripheral card causes said cooling element to be coupled to said peripheral card.

43. The host device of claim 41, further comprising:
a second positionable cooling element coupled to said positioning means;
wherein said movement of said latching means from said first position to said second position causes said positioning means to translate said second cooling element towards said peripheral card.

44. A host device comprising:
a positionable cooling element for dissipating thermal energy generated by a peripheral card inserted into said host device;
a positioning means for positioning said cooling element, coupled to said cooling element; and
a spring loaded locking means coupled to said positioning means, said spring loaded locking means configured to engage said peripheral card;
wherein said engagement of said peripheral card causes said positioning means to translate said cooling element towards said peripheral card.

45. A host device comprising:
a fixed cooling element for dissipating thermal energy generated by a peripheral card; and
means for rotating said peripheral card towards said fixed cooling element.

46. A host device comprising:
a fixed cooling element for dissipating thermal energy generated by a peripheral card; and
means for translating said peripheral card along one or more V-shaped guide tracks towards said fixed cooling element.

47. A host device comprising:
a positionable cooling element for dissipating thermal energy generated by a peripheral card inserted into said host device; and
means for translating said cooling element along a guide track towards said peripheral card.
